(19) United States
(12) Patent Application Publication
(10) Pub. No.: US 2014/0320016 A1
(43) Pub. Date: Oct. 30, 2014

(54) PLASMA GENERATING APPARATUS AND SUBSTRATE TREATING APPARATUS

(71) Applicant: KOREA ADVANCED INSTITUTE OF SCIENCE AND TECHNOLOGY, Daejeon (KR)

(72) Inventors: Hong-Young CHANG, Daejeon (KR); Sang-Hun SEO, Daejeon (KR); Gi-Jung PARK, Daejeon (KR)

(21) Appl. No.: 14/328,867

(22) Filed: Jul. 11, 2014

Related U.S. Application Data
(63) Continuation of application No. PCT/KR2013/000274, filed on Jan. 14, 2013.

(30) Foreign Application Priority Data
Jan. 20, 2012 (KR) 10-2012-0006458

(51) Int. Cl. H01J 37/32; H05H 1/46

(52) U.S. Cl. CPC H01J 37/32541; H01J 37/32091; H05H 1/46; H05H 2001/4675; H05H 2001/4682
USPC 315/111.41

(57) ABSTRACT

A plasma generating apparatus and a substrate processing apparatus are disclosed. The plasma generating apparatus includes a disk-shaped first electrode receiving first RF power of a first frequency to generate plasma, a washer-type second electrode disposed around the circumference of the first electrode and receiving second RF power of a second frequency, an insulating spacer disposed between the first electrode and the second electrode, a first RF power source supplying power to the first electrode, and a second RF power source supplying power to the second electrode.

### CROSS-REFERENCE TO RELATED APPLICATIONS

This application is a continuation of and claims priority to PCT/KR2013/000274 filed on Jan. 14, 2013, which claims priority to Korea Patent Application No. 10-2012-0006458 filed on Jan. 20, 2012, the entirety of which is hereby incorporated by reference herein.

### BACKGROUND

1. Field of the Invention

The present invention described herein generally relates to plasma generating apparatuses and, more particularly, to a capacitively coupled plasma generating apparatus including a plurality of electrodes.

2. Description of the Related Art

In order to generate large-area plasma for semiconductor, a top electrode and a bottom electrode are disposed to be spaced apart from each other. A substrate is disposed on the bottom electrode. RF power applied to the top electrode mainly produces high plasma density, and RF power applied to the bottom electrode adjusts an energy distribution of ions. As substrates continue to increase in size, standing wave effect or the like makes it difficult to accomplish plasma density uniformity of 5 percent that is conventionally required.

### SUMMARY

Embodiments of the present invention provide a plasma generating apparatus supplying RF power to a plurality of electrodes to uniformly process a semiconductor substrate.

A plasma generating apparatus according to an embodiment of the present invention may include a disk-shaped first electrode receiving first RF power of a first frequency to generate plasma; a washer-type second electrode disposed around the circumference of the first electrode and receiving second RF power of a second frequency; an insulating spacer disposed between the first electrode and the second electrode; a first RF power source supplying power to the first electrode; and a second RF power source supplying power to the second electrode.

In an embodiment of the present invention, the plasma generating apparatus may further include a first RF power supply unit supplying power to the first electrode; and a second RF power distribution unit distributing the second RF power to the second electrode.

In an embodiment of the present invention, the second RF power distribution unit may include a power input unit disposed around the circumference of the first RF power supply unit; a second power distribution line branching radially from the power input unit; and a ground member covering the second power distribution line. One end of the second power distribution line is connected to the power input unit, and the other end of the second power distribution line is symmetrically connected to the second electrode.

In an embodiment of the present invention, the second electrode may be divided into a plurality of second electrodes cut on its central axis in a radius direction, and each of the divided second electrodes may be electrically connected to the other end of the second power distribution line.

In an embodiment of the present invention, the first RF power supply unit may include at least one of: a first RF power supply line in contact with the first electrode; a first RF power inner insulating jacket covering the first power supply line; a first RF ground outer cover covering the first RF power inner insulating jacket; and a first RF power outer insulating jacket covering the first RF ground outer cover.

In an embodiment of the present invention, an area of the first electrode may be equal to an area of the divided second electrode.

In an embodiment of the present invention, the second frequency may be different from the first frequency.

In an embodiment of the present invention, a bottom surface of the first electrode and a bottom surface of the second electrode may be different from each other, and the insulating spacer may fill an outer side surface of the first electrode and an inner side surface of the second electrode.

In an embodiment of the present invention, thickness of the first electrode may be equal to thickness of the insulating spacer, and a bottom surface of the second electrode may vary outward.

In an embodiment of the present invention, the plasma generating apparatus may further include at least one of a third RF power source having a third frequency and supplying power to the first electrode; and a fourth RF power source having a fourth frequency and supplying power to the second electrode. Power of the third RF power source is supplied to the first electrode through the first RF power supply unit. Power of the fourth RF power source is supplied to the second electrode through the second RF power supply unit.

In an embodiment of the present invention, the plasma generating apparatus may further include a gas diffusion space receiving a gas through an external gas supply line and formed on the first electrode or the second electrode; and a nozzle connected to the gas diffusion space and penetrating the first electrode or the second electrode.

A plasma generating apparatus according to another embodiment of the present invention may include a first electrode; a second electrode disposed around the circumference of the first electrode; a first RF power source supplying power to the first electrode; a second RF power source supplying power to the second electrode; and a second RF power source distribution unit distributing power to the second electrode. The second electrode may be divided into a plurality of second electrodes.

In an embodiment of the present invention, the first electrode may be disk-shaped, and the second electrode may be washer-type.

In an embodiment of the present invention, the second RF power distribution unit may distribute second RF power to the respective divided second electrodes.

In an embodiment of the present invention, the second RF power distribution unit may include a power input unit receiving second RF power through the second RF power source; a second power distribution line branching radially from the power input unit; and a ground member covering the second power distribution line. The branching power distribution line may be connected to the divided second electrode.

In an embodiment of the present invention, the divided second electrodes may have the same area.

In an embodiment of the present invention, the plasma generating apparatus may further include nozzles formed through the first electrode and the second electrode to supply a gas.

A plasma generating apparatus according to another embodiment of the present invention may include a first electrode; a second electrode disposed around the circumference of the first electrode; a first RF power source supplying power to the first electrode; a second RF power source supplying power to the second electrode; and a second RF power source distribution unit distributing power to the second electrode.

In an embodiment of the present invention, the second RF power distribution unit may include a power input unit receiving second RF power through the second RF power source; a second power distribution line branching radially from the power input unit; and a ground member covering the second power distribution line. The branching power distribution line is connected to the second electrode.

In an embodiment of the present invention, the second electrode may be divided to have the same area.

A plasma generating apparatus according to another embodiment of the present invention may include a first electrode; a second electrode disposed around the circumference of the first electrode; a second RF power source supplying power to the second electrode; and an insulating support disposed between the first electrode and the second electrode and the second RF power distribution unit to have a gas diffusion space.

In an embodiment of the present invention, the second RF power distribution unit may include a power input unit receiving second RF power through the second RF power source; a second power distribution line branching radially from the power input unit; and a ground member covering the second power distribution line. The branching power distribution line may be connected to the second electrode.

In an embodiment of the present invention, the plasma generating apparatus may further include nozzles formed through the first electrode and the second electrode and connected to the gas diffusion space.

A substrate processing apparatus according to an embodiment of the present invention may include a plasma generating unit generating capacitively coupled plasma inside a vacuum container; and a substrate holder disposed to face the plasma generating unit and mounting a substrate. The plasma generating unit may include a first electrode; a second electrode disposed around the circumference of the first electrode; a first RF power source supplying power to the first electrode; a second RF power source supplying power to the second electrode; and a second RF power source distribution unit distributing power to the second electrode.

In an embodiment of the present invention, the plasma generating unit may be mounted inside the vacuum container or mounted on a lid of the vacuum container.

In an embodiment of the present invention, the second electrode may be divided into a plurality of the same second electrodes. The second RF power distribution unit may include a power input unit receiving second RF power through the second RF power source; a second power distribution line branching radially from the power input unit; and a ground member covering the second power distribution line. The branching power distribution line may be connected to the second electrode.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIG. 1 is a perspective view of a plasma generating apparatus according to an embodiment of the present invention.

FIG. 2 is a top plan view of FIG. 1.

FIG. 3 is a cross-sectional view taken along the line I-I′ in FIG. 1.

FIGS. 4 to 6 illustrate plasma generating apparatuses according to other embodiments of the present invention.

FIG. 7 illustrates a plasma generating apparatus according to another embodiment of the present invention.

FIG. 8 illustrates a plasma generating apparatus according to another embodiment of the present invention.

FIG. 9 illustrates a plasma generating apparatus according to a modified embodiment of the present invention.

FIG. 10A illustrates a plasma generating apparatus according to another embodiment of the present invention.

FIG. 10B is a cross-sectional view taken in another direction of FIG. 10A.

FIG. 11A illustrates a plasma generating apparatus according to another embodiment of the present invention.

FIG. 11B is a cross-sectional view taken along the line II-IP in FIG. 11A.

FIG. 12 illustrates a plasma generating apparatus according to another embodiment of the present invention.

FIG. 13 illustrates a plasma generating apparatus according to another embodiment of the present invention.

FIGS. 14 to 17 illustrate results of measuring plasma density distributions according to an embodiment of the present invention.

### DETAILED DESCRIPTION

A diameter of a semiconductor substrate is 300 millimeters (mm) and will increase to 450 mm in the near future. Recently, a capacitively coupled plasma apparatus for 300 mm substrates has been developed. There is a need for developing a capacitively coupled plasma generating apparatus for 450 mm substrates while keeping basic characteristics of the conventional capacitively coupled plasma generating apparatus for 300 mm substrates.

A plasma generating apparatus according to an embodiment of the present invention uses an inner electrode and an outer electrode that are insulated from each other to ensure uniformity of large-area plasma. The outer electrode is divided to divided outer electrodes having substantially the same area. In addition, an area of the inner electrode is substantially equal to an area of the divided outer electrode. Thus, the inner electrode and the divided outer electrode may have substantially the same impedance. The inner electrode may be applied with low-frequency RF power, and the divided outer electrode may be applied with high-frequency RF power. The high-frequency RF power may have high probability of plasma generation. Accordingly, although plasma generated at the divided outer electrode is diffused to be lost, the level of power consumed at the inner electrode may be nearly equal to that of power consumed at the outer electrode.

Each of the divided outer electrodes may receive RF power. In order achieve this, an RF power distribution unit for an outer electrode may receive power at one point and output the power to a plurality of points. The RF power distribution unit may have the same power line length to equivalently supply impedance to the respective points. In addition, the RF power distribution unit may have a coaxial cable structure to block an external influence.

The invention will now be described more fully hereinafter with reference to the accompanying drawings, in which embodiments of the invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

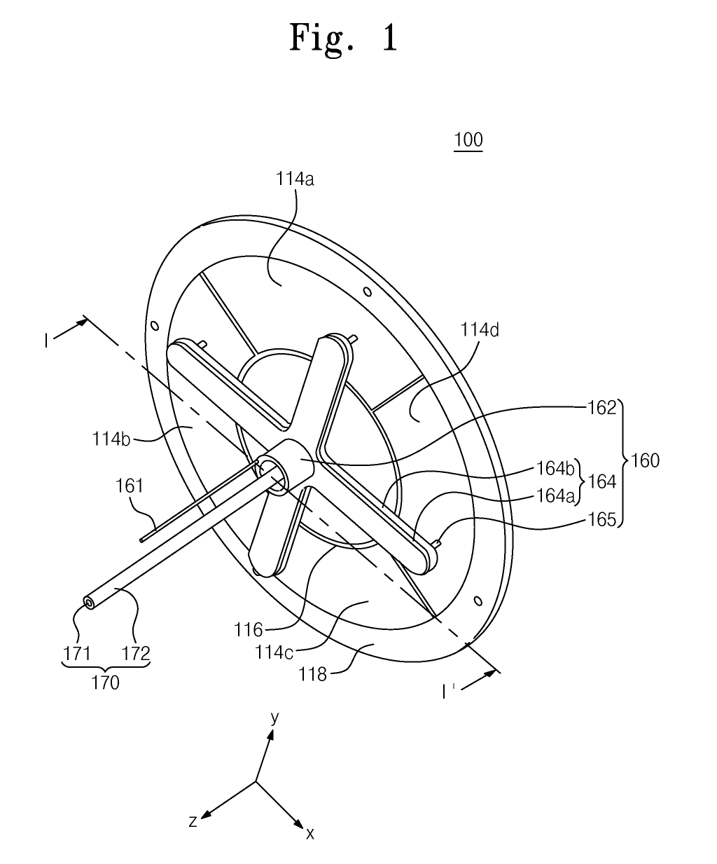

FIG. 1 is a perspective view of a plasma generating apparatus according to an embodiment of the present invention.

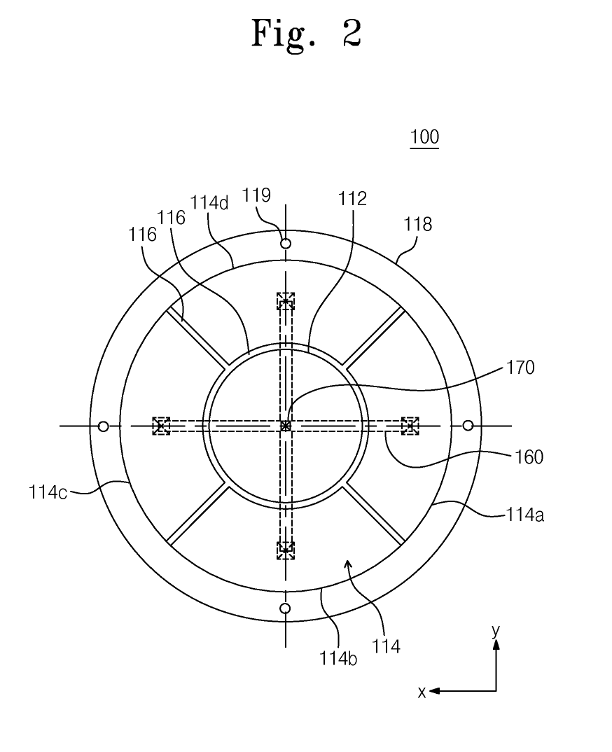

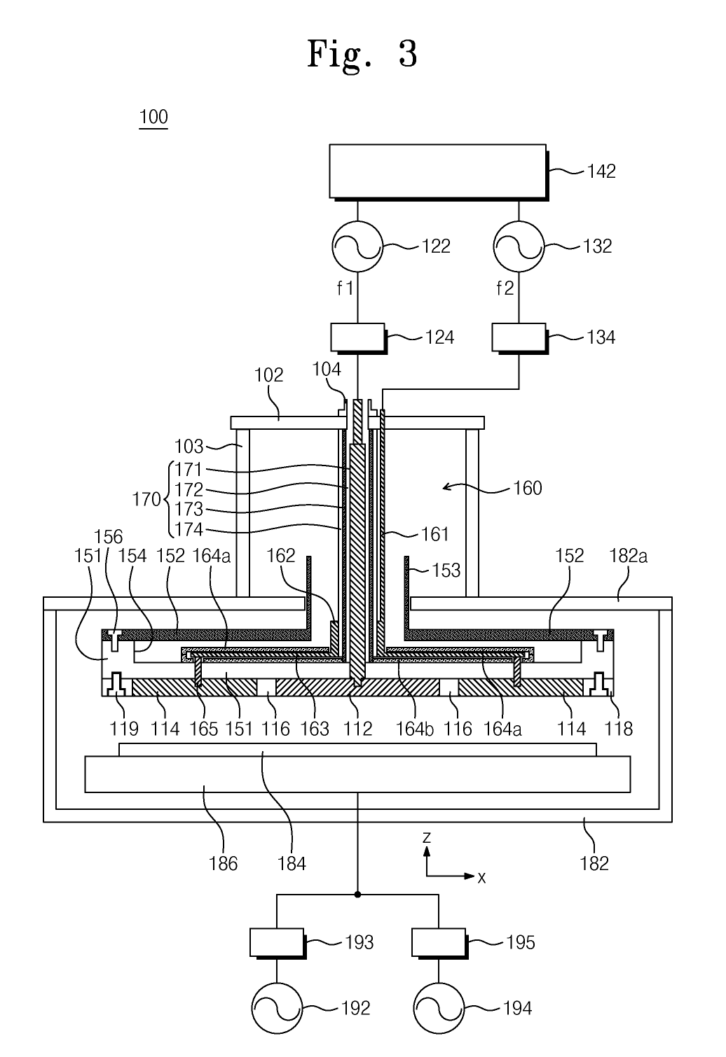

FIG. 2 is a top plan view of FIG. 1. FIG. 3 is a cross-sectional view taken along the line I-I′ in FIG. 1.

Referring to FIGS. 1 to 3, a plasma generating apparatus 100 includes a disk-shaped first electrode 112 receiving first RF power of a first frequency to generate plasma, a washer-type second electrode 114 disposed around the circumference of the first electrode 112 and receiving second RF power of a second frequency, an insulating spacer 116 disposed between the first electrode 112 and the second electrode 114, a first RF power source 122 supplying power to the first electrode 112, and a second RF power source 132 supplying power to the second electrode 114.

The plasma generating apparatus 100 includes a substrate holder 186 disposed opposite to the first electrode 112 and the second electrode 114 to mount a substrate 184. The plasma generating apparatus 100 may perform an etching process, a deposition process or a cleaning process.

A vacuum container 182 may include a gas supply unit (not shown) and an exhaust unit (not shown). The vacuum container 182 may be cylindrical. The vacuum container 182 may include a cylindrical body part and a top plate 182a to cover an open top of the body part.

The substrate holder 186 may be disk-shaped. The substrate holder 186 may include an electrostatic chuck or a mechanical chuck to mount a substrate. The substrate may be a 450 mm semiconductor substrate. The substrate holder 186 may be disposed inside the vacuum container 182 to face the first electrode 112 and the second electrode 114 of the plasma generating apparatus 100.

A low-frequency RF power source 192 and a high-frequency RF power source 194 may be connected to the substrate holder 186. Power of the low-frequency RF power source 192 may be supplied to the substrate holder 186 through a low-frequency impedance matching network 193. Power of the high-frequency RF power source 194 may be supplied to the substrate holder 186 through a high-frequency impedance matching network 195. An output of the low-frequency impedance matching network 193 and an output of the high-frequency impedance matching network 195 are combined to be provided to one point or a plurality of points of the substrate holder 186.

One surface of the first electrode 112, one surface of the second electrode 114, and one surface of the insulating spacer 116 may be the same plane. The other surface of the first electrode 112, the other surface of the second electrode 114, and the other surface of the insulating spacer 116 may be the same plane.

The first electrode 112 may be disk-shaped. A diameter d1 of the first electrode 112 may be about 105 mm. Width g of the insulating spacer 116 may be between several millimeters (mm) and tens of millimeters (mm).

The second electrode 114 may be in the form of a washer and may be symmetrically cut in a diameter direction on the central axis of the second electrode 114. Preferably, the second electrode 114 may be divided into four second electrodes. The divided second electrodes may be separated from each other through the insulating spacer 116. The divided second electrodes may have the same shape and area. An area of the divided second electrode and an area of the first electrode 112 may be substantially equal to each other. Width d2 of the second electrode 114 may be about 110 mm. An outer diameter d of the second electrode 114 may be about 450 mm. Spaces between the divided second electrodes may be filled with the insulating spacer 116.

The first electrode 112 and the second electrode 114 may be separated from each other. Thus, mutual interference between the first electrode 112 and the second electrode 114 may be minimized. A second frequency f2 may be greater than a first frequency f1. For example, the first frequency f1 may be 13.56 MHz and the second frequency f2 may be 60 MHz.

The first electrode 112 and the second electrode 114 may be made of a conductive material such as aluminum whose surface is coated with an insulator. The insulating spacer 116 may be made of a dielectric material. The insulating spacer 116 may be alumina, ceramic or sapphire.

An outer insulating part 118 may be disposed on the same plane as the first electrode 112 around the outside of the second electrode 114. The outer insulating part 118 may be washer-type and may be made of a dielectric material.

An insulating support 151 may be disposed on the outer insulating part 118, the second electrode 114, the insulating spacer 116, and the first electrode 112. The insulating support 151 may be combined with the outer insulating part 118 through fixing means 119. The insulating support 151 may be made of a dielectric material.

One surface of the insulating support 151 may be in contact with one surface of the first electrode 112. A depression 154 may be formed on the other surface of the insulating support 151. A diameter of the depression 154 may be greater than that of the first electrode 112. A second RF power distribution unit 160 may be inserted into the depression 154.

A cover part 152 may have the same diameter as the insulating support 151. The cover part 152 may be in contact with the other surface of the insulating support 151 and may be combined with the insulating support 151 by combination means 156. The cover part 152 may be disk-shaped and may be made of a conductive material. The cover part 152 may be connected to a cylindrical extension part 153.

The extension part 153 may be disposed in the center of the cover part 152. The extension part 153 may protrude to the outside via a through-hole formed on a top plate 182a of the vacuum container 182. The inside of the extension part 153 may be in an atmospheric pressure state.

Power of the first RF power source 122 may be supplied to the first electrode 112 through a first impedance matching network 124. An output of the first impedance matching network 124 may supply power to the center of the first electrode 112 through the first RF power supply unit 170 having a coaxial cable structure.

According to a modified embodiment of the present invention, the first RF power supply unit 170 may supply first RF power to the first electrode 112 at another position other than the center of the first electrode 112. In addition, the first RF power supply unit 170 may not be fabricated in one body with the second RF power distribution unit 160 and may be spatially separated from each other.

Power of the second RF power source 132 may be supplied to a plurality of positions of the second electrode 114 through a second impedance matching network 134. An output of the second impedance matching network 134 may be provided to a plurality of positions of the second electrode 114 through the second RF power distribution unit 160 distributing second RF power.

A control unit 142 may control a ratio of power of the first RF power source 122 to power of the second RF power source 132. Thus, the plasma uniformity is controlled. When the second electrode 114 is divided into four second electrodes, the second RF power may be four times larger than the first RF power.

The second RF power distribution unit 160 may distribute the second RF power to the second electrode 114 to have the same impedance. The second RF power distribution unit 160 may include a cylindrical power input unit 162 covering the first RF power supply unit 170, a second power distribution line 163 radially branching from the power input unit 162 with symmetry, and a ground member 164 covering the second power distribution line 163. One end of the second power distribution line 163 is symmetrically connected to the power input unit 162, and the other end thereof may be symmetrically connected to the second electrode 114 through a connection pillar 165. The power input unit 162 may receive the second RF power through a second RF power supply line 161.

The second RF power distribution unit 160 supplies power to the second electrode 114 at a plurality of positions. If impedances in a direction to view the electrode 214 of respective four branches are different from each other, the power of the second RF power source 132 is concentrated on some branches. Thus, each branch of the second RF power distribution unit 160 has a coaxial cable structure and the same length to have the same impedance.

The second RF power distribution unit 160 may distribute the second RF power to the divided second electrodes. The divided second electrodes may have the same shape and structure to have the same impedance. In addition, the second power distribution unit 160 may have the same the same coaxial cable structure and the same branch structure to have the same impedance. Thus, the second power distribution unit 160 may have the same impedance and distribute power to the divided second electrodes.

According to a modified embodiment of the present invention, the second power distribution unit 160 may be disposed not inside but outside a vacuum container. In addition, the second power distribution unit 160 may have a transformer structure and distribute power to the divided second electrodes.

The ground member 164 may include an upper ground member 164a and a lower ground member 164. The upper ground member 164a and the lower ground member 164b may be combined with each other. A trench is formed at the inside of the ground member 164, and the second power distribution line 163 is disposed in the trench. An insulating member (not shown) may be interposed between the ground member 164 and the second power distribution line 163 to prevent an electrical contact between the ground member 164 and the second power distribution line 163.

The second power distribution line 163 may have four branches disposed radially. The second power distribution line 163 may have azimuthal symmetry. One end of the second power distribution line 163 is connected to the circumference of the power input unit 162. The other end of the second power distribution line 163 is connected to the divided second electrode 114 through the connection pillar 165. A sealing member is disposed around the connection pillar 165 to keep a vacuum. The connection pillar 165 combines the second power distribution line 163 with the divided second electrode 114 to fix them.

The first RF power supply unit 170 may have a coaxial cable shape and supply power to the center of the first electrode 112. The first RF power supply unit 170 may include a first RF power supply line 171 in contact with the first electrode 112, a first RF power inner insulating jacket 172 covering the first power supply line 171, a first RF ground outer cover 173 covering the first RF power inner insulating jacket 172, and a first RF power outer insulating jacket 174 covering the first RF ground outer cover 173.

One end of the first power supply line 171 is disposed to penetrate the center of the ground member 164. The first RF power supply line 171 is fixed to the center of the first electrode 112 through the center of the insulating support 151. A sealing member is disposed around one end of the first RF power supply line 171 to keep vacuum.

The other end of the first RF power supply unit 170 is connected to an electrical connector 104. The electrical connector 104 is fixed to a support plate 102. The support plate 102 may be fixed to a top plate 182a of the vacuum container 182 through a support pillar 103.

According to a modified embodiment of the present invention, the first RF power supply unit 170 may have a coaxial cable structure and may be disposed to be spatially separated from the second power distribution unit 160.

According to a modified embodiment of the present invention, the first electrode 112 may include first nozzles (not shown) to supply a gas into the vacuum container 182. The second electrode 114 may include second nozzles (not shown) to supply a gas into the vacuum container 182. The first nozzles may be connected to each other through a trench formed on one surface of the first electrode 112 or one surface of an insulating support plate. The second nozzles may be connected to each other through a trench formed one surface of the second electrode 114 or one surface of the insulating support plate.

According to a modified embodiment of the present invention, a gas diffusion space (not shown) may be formed on the first electrode 112 and the second electrode 114. Specifically, the gas diffusion space may be formed between the first electrode 112 or the second electrode 114 and the second power distribution unit 160. The gas diffusion space may be formed at the insulating support plate.

According to a modified embodiment of the present invention, the first frequency and the second frequency may be identical to each other.

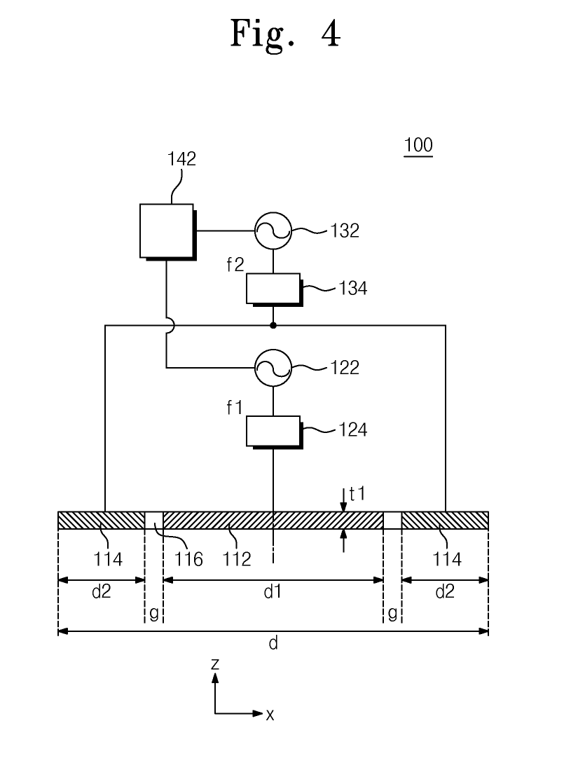

FIGS. 4 to 6 illustrate plasma generating apparatuses according to other embodiments of the present invention.

Referring to FIG. 4, one surface of a first electrode 112, one surface of a second electrode 114, and one surface of an insulating spacer 116 may be the same plane. The other surface of the first electrode 112, the other surface of the second electrode 114, and the other surface of the insulating spacer 116 may be the same plane. Thickness t1 of the first electrode 112 may be equal to thickness t2 of the second electrode 114. The second electrode 114 may be divided into four second electrodes.

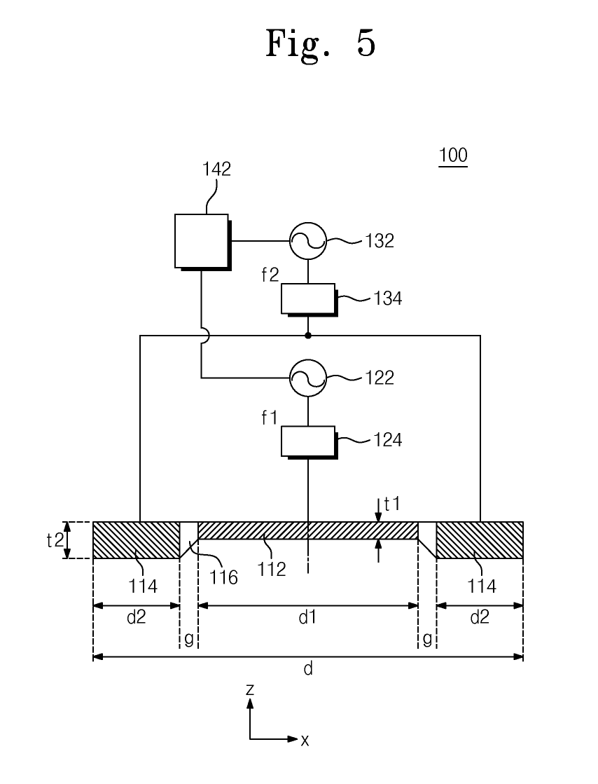

Referring to FIG. 5, thickness t1 of a first electrode 112 may be smaller than thickness t2 of a second electrode 114, and an insulating spacer 116 increases in thickness outward. One surface of the first electrode 112, one surface of the second electrode 114, and one surface of the insulating spacer 116 may be the same plane. The second electrode 114 may be divided into four second electrodes.

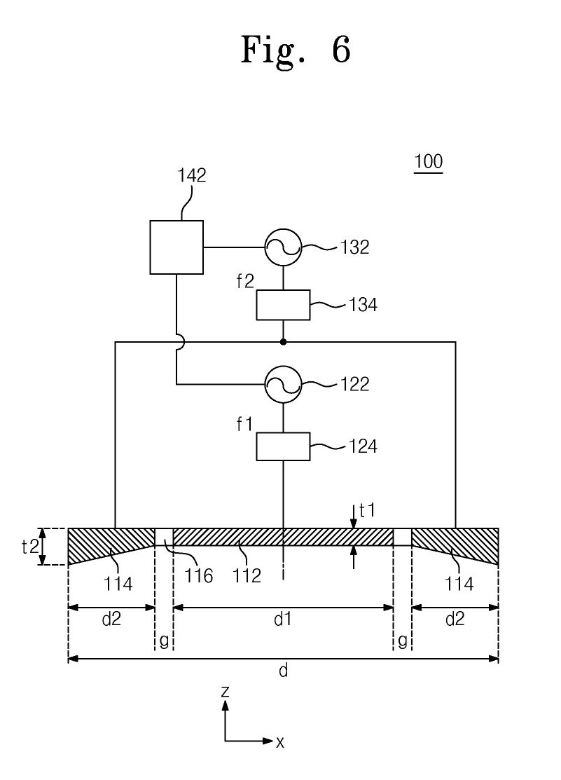

Referring to FIG. 6, thickness t1 of a first electrode 112 may be equal to thickness of an insulating spacer 116. Thickness t2 of a second electrode 114 may increase outward. One surface of the first electrode 112, one surface of the second electrode 114, and one surface of the insulating spacer 116 may be the same plane. The second electrode 114 is divided into four second electrodes.

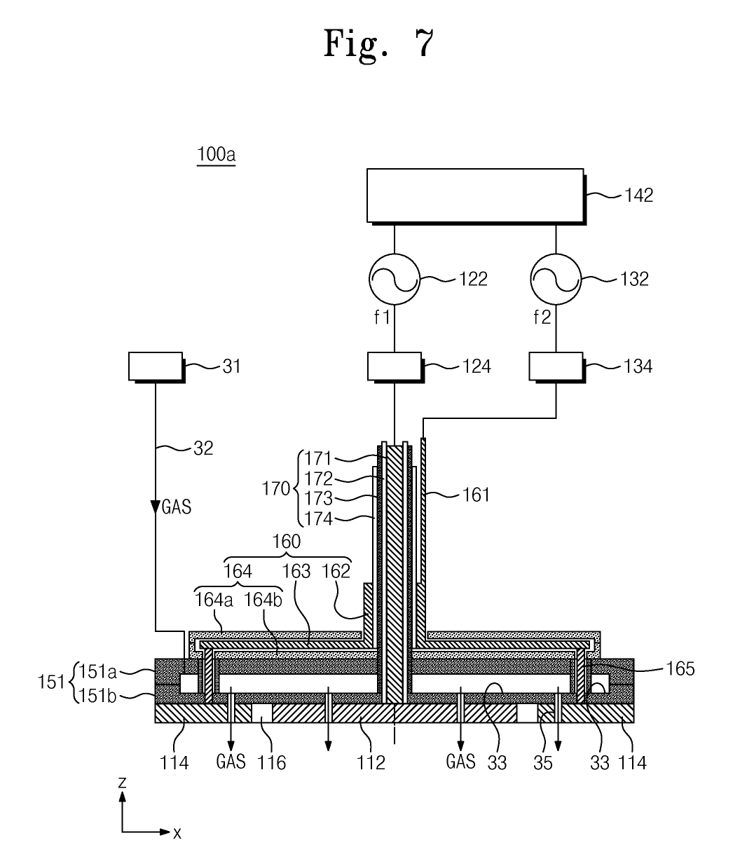

FIG. 7 illustrates a plasma generating apparatus according to another embodiment of the present invention.

Referring to FIG. 7, a plasma generating apparatus 100a according to an embodiment of the present invention includes a first electrode 112, a second electrode 114 disposed around the circumference of the first electrode 112, a second power distribution unit 160 distributing power to the second electrode 114, and an insulating support 151 disposed between the first electrode 112 and the second 114 and the second power distribution unit 160 to have a gas diffusion space 33.

The insulating support 151 includes an upper insulating support 151a and a lower insulating support 151b. The upper insulating support 151a and the lower insulating support 151b are combined with each other. A depression may be formed on a bottom surface of the upper insulating support 151a or a top surface of the lower insulating support 151b. The depression may forms a gas diffusion space 33.

The gas diffusion space 33 receives a gas from a gas storage 31 through an external gas line 32. Preferably, the gas diffusion space 33 is disposed over the first electrode 112 or the second electrode 114 and is a single space.

A nozzle 35 may be connected to the gas diffusion space 33 to be formed through the first electrode 112 or the second electrode 114. The nozzle 35 may inject a gas.

A second RF power distribution unit 160 may include a power input unit 162 receiving second RF power through a second RF power source 132, a second power distribution line 163 branching radially from the power input unit 162, and a ground member 164 covering the second power distribution line 163. The branching second power distribution line 163 may be connected to a divided second electrode 114.

A connection pillar 165 may penetrate the gas diffusion space 33 or the insulating support 151 to connect the second power distribution line 163 to the divided second electrode 114. The connection pillar 165 may have a coaxial cable structure.

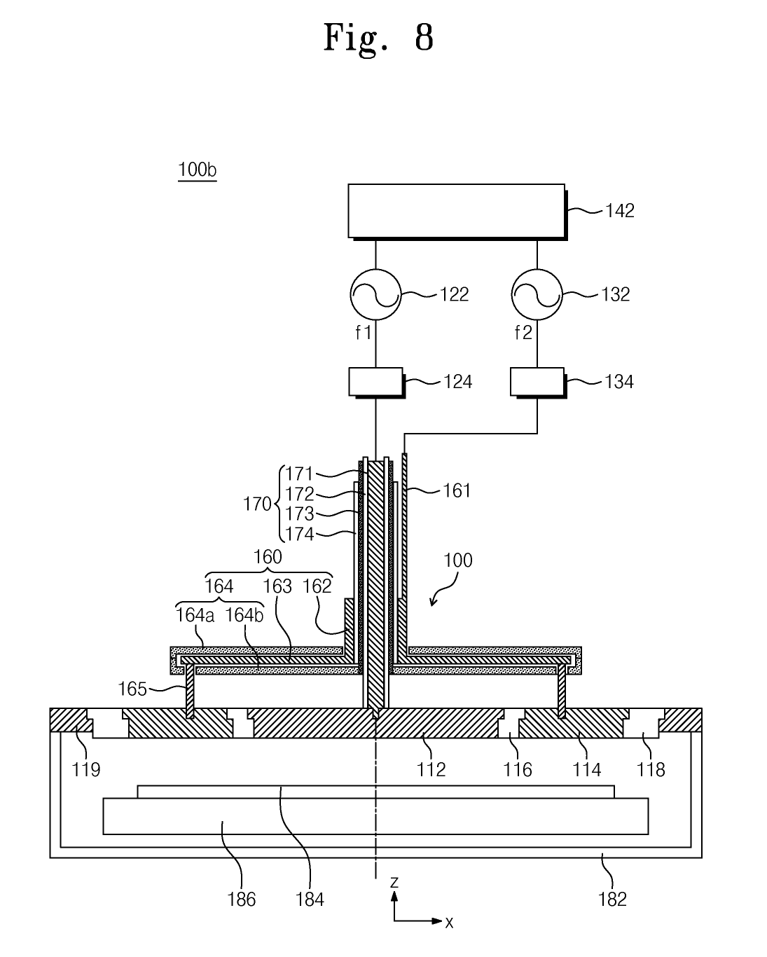

FIG. 8 illustrates a plasma generating apparatus according to another embodiment of the present invention.

Referring to FIG. 8, a plasma generating apparatus 100b includes a first electrode 112, a second electrode 114 disposed around the circumference of the first electrode 112, a first RF power source 122 supplying power to the first electrode 112, a second RF power source 132 supplying second RF power to the second electrode 114, and a second RF power distribution unit 160 distributing power to the second electrode 114. The second electrode 114 is divided into a plurality of second electrodes.

The first electrode 112 may be disk-shaped, and the second electrode 114 may be washer-type. The second electrode 114 may be radially divided, and the divided second electrodes 114 may have the same area.

The second RF power distribution unit 160 may distribute power to the divided second electrodes 114.

The second RF power distribution unit 160 may include a power input unit 162 receiving second RF power through the second RF power source 132, a second power distribution line 163 branching radially from the power distribution unit 162, and a ground member 164 covering the second power distribution line 163. The branching second power distribution line 163 may be connected to the divided second electrode 114.

One surface of the first electrode 112, one surface of the second electrode 114, and one surface of the insulating spacer 116 may be the same plane. The other surface of the first electrode 112, the other surface of the second electrode 114, and the other surface of the insulating spacer 116 may be the same plane.

An outer circumference of the first electrode 112 may have a raised spot. In addition, an inner side and an outer side of the insulating spacer 116 may have a raised spot. Thus, the insulating spacer 116 and the second electrode 114 may be insertibly coupled with each other and the first electrode 112 and the insulating spacer 116 may be insertibly coupled with each other. The insulating spacer 116 may extend to a space between the divided second electrodes 114.

An outer insulating part 118 may be disposed on the same plane as the first electrode 112 around the outer circumference of the second electrode 114. The outer insulating part 118 may be washer-type and may be made of a dielectric material. An outer circumference and an inner circumference of the outer insulating part 118 may have a raised spot. Thus, the outer insulating part 118 may be insertibly coupled with the second electrode 114.

A top plate 119 may be disposed at the circumference of the outer insulating part 118. The top plate 119 may be washer-type, and an inner circumference of the top plate 119 may have a raised spot. Thus, the top plate 119 and the outer insulating part 1198 may be insertibly coupled with each other.

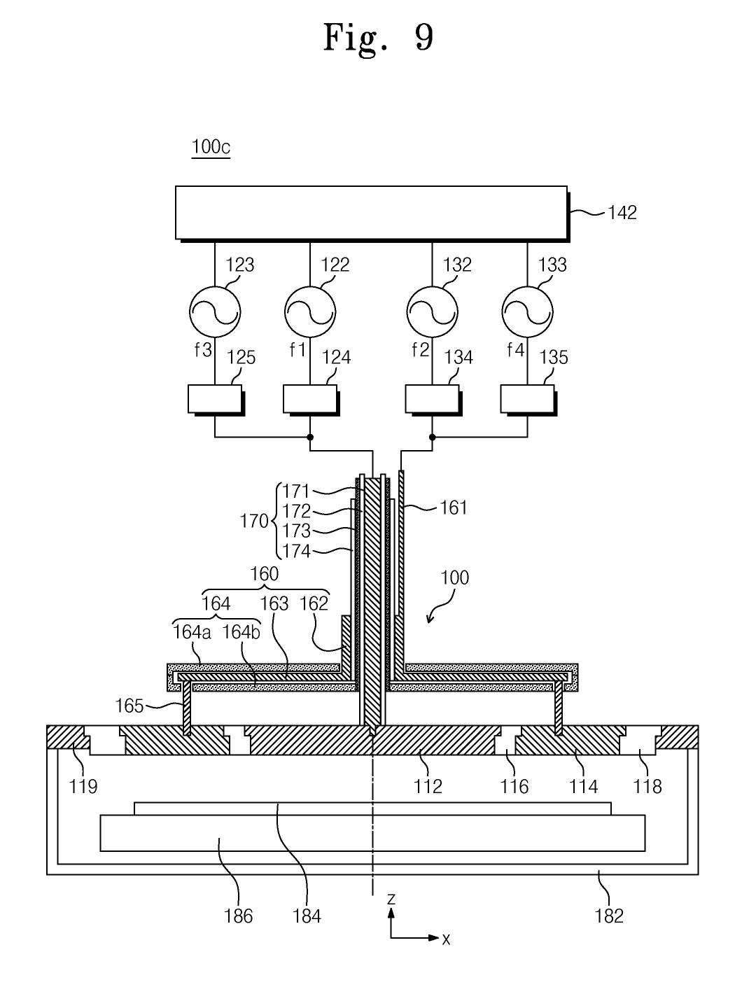

FIG. 9 illustrates a plasma generating apparatus 100c according to a modified embodiment of the present invention. In FIG. 9, sections different from FIG. 8 will be extensively described to avoid duplicate description.

Referring to FIG. 9, the plasma generating apparatus 100c may include a third RF power source 123 having a third frequency and supplying power to a first electrode 112 and a fourth RF power source 133 having a fourth frequency and supplying power to a second electrode 114. Power of a first RF power source 122 and the power of the third power source 123 may be supplied to the first electrode 112 through a first RF power supply unit 170. Power of a second RF power source 132 and the power of the fourth RF power source 133 may be supplied to the second electrode 114 through a second RF power distribution unit 160. The second electrode 114 may be divided into a plurality of second electrodes.

A control unit 142 may control plasma uniformity by adjusting the powers of the first and third RF power sources 122 and 123 and the powers of the second and fourth RF power sources 132 and 133. An output of the third RF power source 123 may be combined with an output of a first impedance matching network 124 through a third impedance matching network 125. An output of the fourth RF power source 133 is combined with an output of a second impedance matching network 134 through a fourth impedance matching network 135.

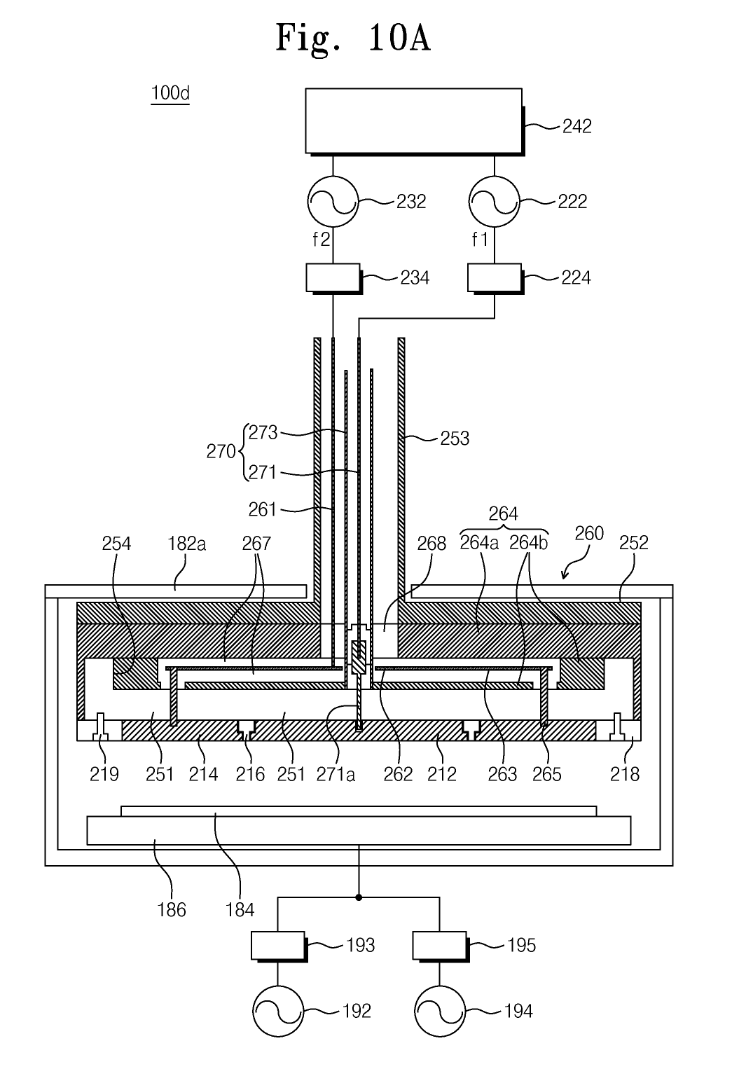

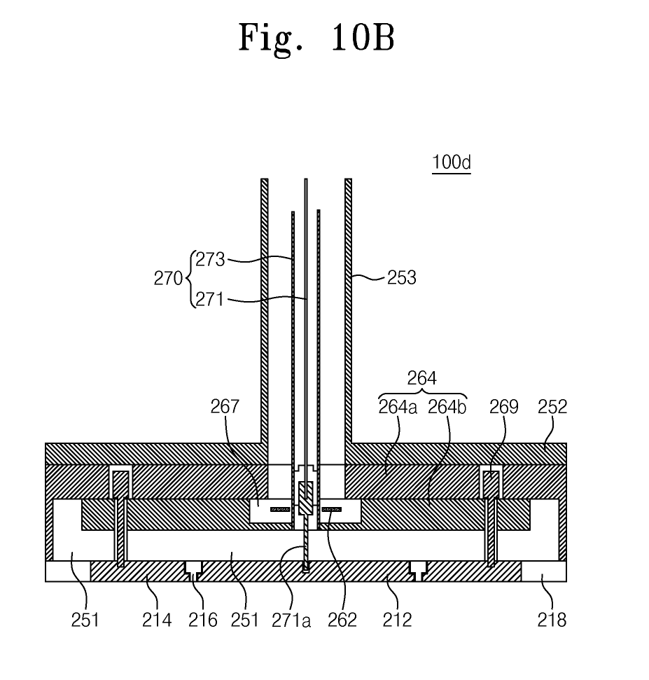

FIG. 10A illustrates a plasma generating apparatus according to another embodiment of the present invention, and FIG. 10B is a cross-sectional view taken in another direction of FIG. 10A.

Referring to FIGS. 10A and 10B, a plasma generating apparatus 100d includes a first electrode 212, a second electrode 214 disposed around the circumference of the first electrode 212, a first RF power source 222 supplying power to the first electrode 212, a second RF power source 232 supplying power to the second electrode 214, and a second RF power distribution unit 260 distributing power to the second electrode 214.

A vacuum container 182 may include a gas supply unit (not shown) and an exhaust unit (not shown). The vacuum container 182 may be cylindrical. The vacuum container 182 may include a cylindrical body part and a top plate 182a covering an open top of the body part.

A substrate holder 186 may be disk-shaped. The substrate holder 186 may include an electrostatic chuck or a mechanical chuck to mount a substrate. The substrate may be a 450 mm semiconductor substrate. The substrate holder 186 may be disposed inside the vacuum container 182 to face the first electrode 212 and the second electrode 1214 of the plasma generating apparatus 100d.

A low-frequency RF power source 192 and a high-frequency RF power source 194 may be connected to the substrate holder 186. Power of the low-frequency RF power source 192 may be supplied to the substrate holder 186 through a low-frequency impedance matching network 193. Power of the high-frequency RF power source 194 may be supplied to the substrate holder 186 through a high-frequency impedance matching network 195. An output of the low-frequency impedance matching network 193 and an output of the high-frequency impedance matching network 195 are combined to be provided to one point or a plurality of points of the substrate holder 186.

The plasma generating apparatus 100d may include the first electrode 212, the second electrode 214, and the insulating spacer 216. The first electrode 212, the second electrode 214, and the insulating spacer 216 may be variously modified.

One surface of the first electrode 212, one surface of the second electrode 214, and one surface of the insulating spacer 2116 may be the same plane. The other surface of the first electrode 212, the other surface of the second electrode 214, and the other surface of the insulating spacer 216 may be the same plane. The second electrode 214 may be washer-type and may be divided into a plurality of second electrodes in a radius direction on its central axis. The insulating spacer 216 may extend to a space between the divided second electrodes.

An outer insulating part 218 may be disposed on the same plane as the first electrode 212 around the outside of the second electrode 214. The outer insulating part 218 may be washer-type and may be made of a dielectric material.

An insulating support 215 may be disposed on the outer insulating part 218, the second electrode 214, the insulating spacer 216, and the first electrode 212. The insulating support 251 may be combined with the outer insulating part 218 through fixing means 219. The insulating support 251 may be made of a dielectric material.

One surface of the insulating support 251 may be in contact with one surface of the first electrode 212. A depression 254 may be formed on the other surface of the insulating support 251. A diameter of the depression 254 may be greater than that of the first electrode 212.

A cover part 252 may have disk-shaped and may be disposed on the insulating support 251. The cover part 252 may be disk-shaped and may be made of a conductive material. The cover part 252 may be connected to a cylindrical extension part 253. The extension part 253 may be disposed in the center of the cover part 252. The extension part 253 may protrude to the outside via a through-hole formed on a top plate 182a. The inside of the extension part 253 may be in an atmospheric pressure state.

Power of the first RF power source 222 may be supplied to the first electrode 212 through a first impedance matching network 224. An output of the first impedance matching network 224 may supply power to the first electrode 212 through the first RF power supply unit 270 having a coaxial cable structure.

Power of the second RF power source 232 may be supplied to a plurality of positions of the second electrode 214 through the second impedance matching network 234. An output of the second impedance matching network 234 may be supplied to the divided second electrode 214 through the second RF power distribution unit 260 distributing second RF power.

A control unit 242 controls a ratio of the power of the first RF power source 222 to the power of the second RF power source 232. Thus, plasma uniformity is controlled.

The second RF power distribution unit 260 may distribute the second RF power to have the same impedance at a plurality of positions of the second electrode 214. The second RF power distribution unit 260 includes a disk-shaped power input unit 262, a second power distribution line 263 radially branching from the power input unit 262 with symmetry, and a ground member 264 covering the second power distribution line 263. One end of the power distribution line 263 may be symmetrically connected to the power input unit 262, and the other end thereof may be symmetrically connected to the second electrode 214 through a connection pillar 265. The power input unit 262 may receive power through the second RF power supply line 261.

The second RF power distribution unit 260 supplies power to a plurality of positions of the second electrode 214. If impedances in direction to view the electrode 214 of respective four branches are different from each other, the power of the second RF power source 232 is concentrated on some branches. Thus, each branch of the second RF power distribution unit 260 has a coaxial cable structure and the same length to have the same impedance.

The ground member 264 may include an upper ground member 264a and a lower ground member 264b. The upper ground member 264a and the lower ground member 264b may be combined with each other. The upper ground member 264a may be disposed between the cover part 252 and the insulating support 251. The lower ground member 264b may be disk-shaped, and a trench may be formed at the inside of the lower ground member 264b. The second power distribution line 263 may be disposed in the trench. The insulating member 267 may be interposed between the ground member 264 and the second power distribution line 263 to prevent an electrical contact between the ground member 264 and the second power distribution line 263. The fixing means 269 may connect to the second electrode through the upper ground member 264a, the lower ground member 264b, and the insulating support 251.

The power distribution line 263 may have four branches. The power distribution line 263 may have azimuthal symmetry. One end of the power distribution line 263 is connected to the circumference of the power input unit 262, and the other end thereof is connected to the second electrode 214 through a connection pillar 265. The connection pillar 265 combines the power distribution line 263 with the second electrode 214 to fix them.

The first RF power distribution unit 270 may have a coaxial cable structure and supply power to the center of the first electrode 212. The first RF power supply unit 270 may include a first RF power supply line 271 in contact with the first electrode 212 and a first RF ground outer cover 273 covering the first RF power supply line 271. The RF power supply line 271 may be fixedly connected to the first electrode 212 through a connection member 271a. A cylindrical insulating fixing member 268 may be disposed around the circumference of the connection member 271a.

One of the first power supply unit 270 may be disposed to penetrate the center of the ground member 264. The first RF power supply line 271 may be fixed to the center of the first electrode 212 through the center of the insulating support 251. One end of the first RF power supply line 271 is connected to the first electrode 212.

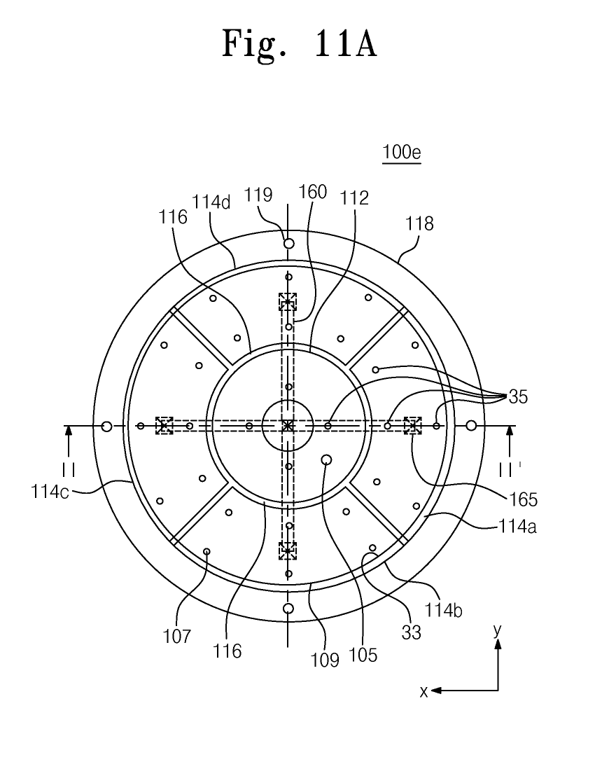

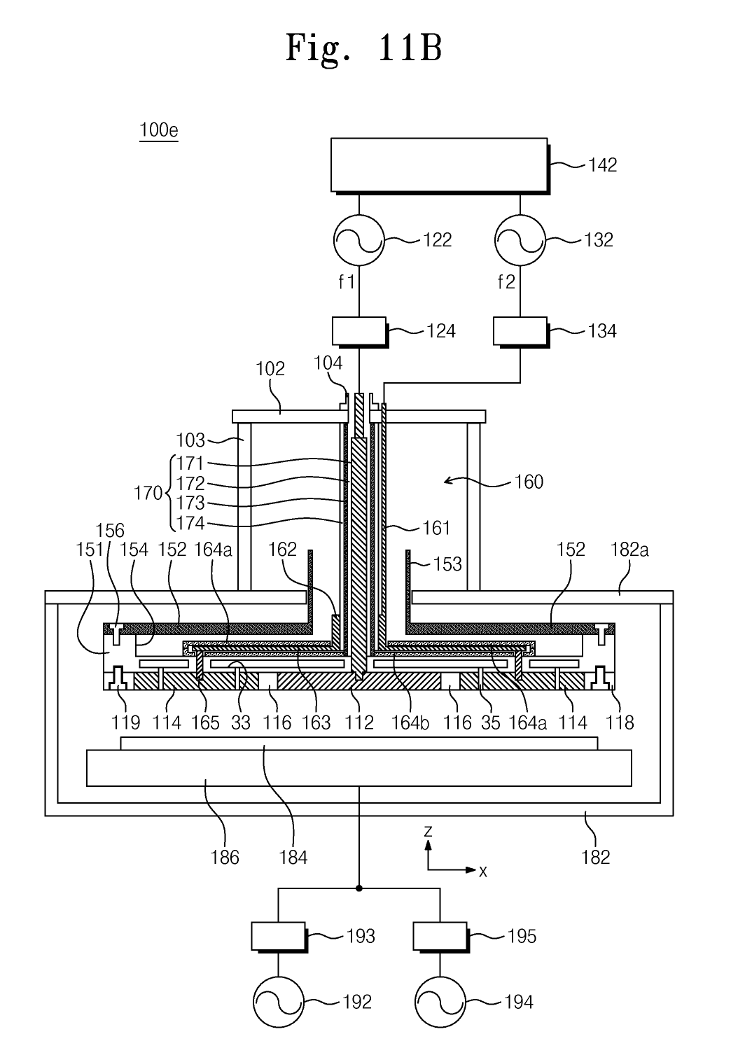

FIG. 11A illustrates a plasma generating apparatus according to another embodiment of the present invention, and FIG. 11B is a cross-sectional view taken along the line II-IP in FIG. 11A. In FIGS. 11A and 11B, sections different from FIGS. 1 to 3 will be extensively described to avoid duplicate description.

Referring to FIGS. 11A and 11B, a plasma generating apparatus 100e includes a first electrode 112, a second electrode 114 disposed around the circumference of the first electrode 112, a second power distribution unit 160 distributing power to the second electrode 114, and an insulating support 151 disposed between the first electrode 112 and the second electrode 114 to have a gas diffusion space 33.

The second electrode 114 may be divided into a plurality of second electrodes. Each of the divided second electrodes 114 receives power through the second power distribution unit 160. Preferably, the gas diffusion space 33 may be washer-type and may be a single space. Thus, a gas supplied through an external gas supply line may be injected through nozzles 35 after being stored and diffused in the gas diffusion space 33. The nozzle 35 may be disposed through the first electrode 112 and the second electrode 114. The connection pillar 165 may have a coaxial cable structure and may be disposed to penetrate the gas diffusion space 33 and the insulating support 151. The connection pillar 165 may electrically connect the second power distribution line 163 to the divided second electrodes 114.

The first RF power supply unit 170 may have a coaxial cable structure and supply power to the center of the first electrode 112 through the center of the gas diffusion space 33.

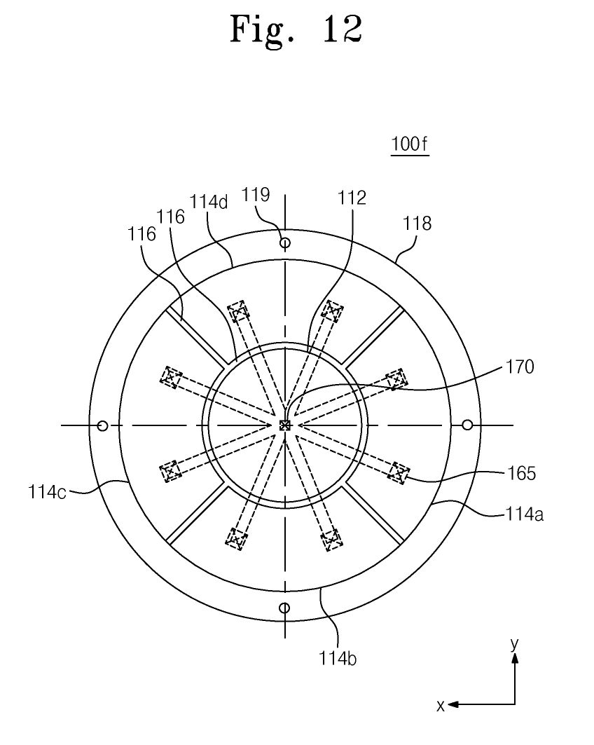

FIG. 12 illustrates a plasma generating apparatus according to another embodiment of the present invention. In FIG. 12, sections different from FIGS. 1 to 3 will be extensively described to avoid duplicate description.

Referring to FIG. 12, second electrode 114a to 114b may have washer-type and may be divided into a plurality of second electrodes 114a to 114b in a radius direction. Each of the divided second electrodes 114a to 114b may receive power at two or more positions through a second power distribution unit 160. An output impedance of a second electrode direction may be equal at a branching point of the second power distribution unit 160.

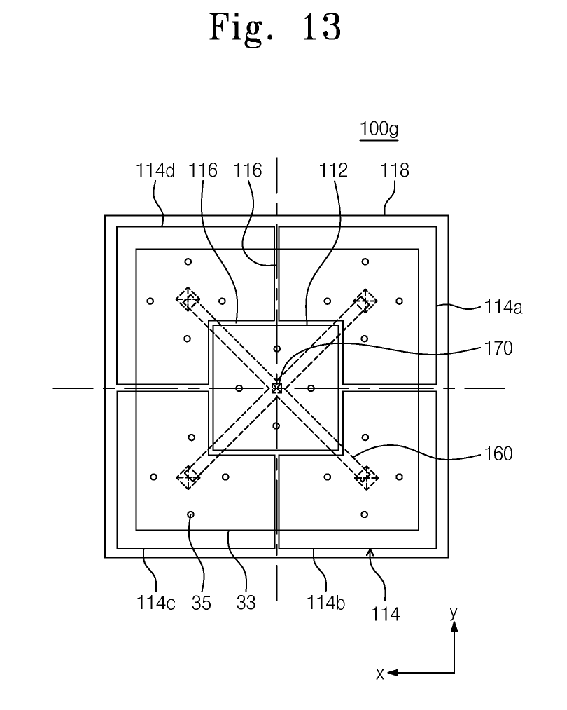

FIG. 13 illustrates a plasma generating apparatus according to another embodiment of the present invention. In FIG. 13, sections different from FIGS. 1 to 3 will be extensively described to avoid duplicate description.

Referring to FIG. 13, a first electrode 112 may have a shape of square. Second electrodes 114a to 114d may have a shape of square ring to cover the first electrode 112. The second electrodes 114a to 114d may be divided into four second electrodes on the central axis. The divided second electrodes 114a to 114d may have a shape of which a portion of corner is quadrangularly removed. A gas diffusion space 33 may be formed on the first electrode 112 and the second electrodes 114a to 114d to supply a gas to a substrate through a nozzle 35.

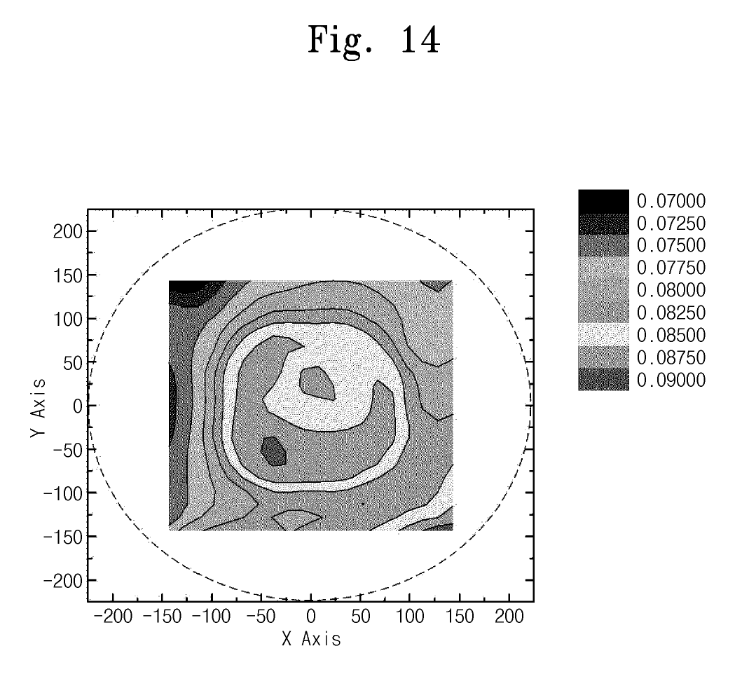

FIGS. 14 to 17 illustrate results of measuring plasma density distributions according to an embodiment of the present invention.

Referring to FIGS. 14 to 17, a plasma generating apparatus in FIG. 1 was used. A substrate holder is removed, and an electrical probe array is disposed at a position of the substrate holder. Plasma density measured using the electrical probe array was fitted and two-dimensionally displayed. A second electrode was divided into four second electrodes to be washer-type. A unit of the plasma density is 10̂10/cm³. Electrical probe arrays are two-dimensionally arranged in a region of 300 mm×300 mm at regular intervals.

A diameter of a first electrode is 105 mm, and width of the second electrode is 110 mm. A first frequency of first RF power applied to the first electrode is 8 MHz, and a second frequency of second RF power is 13.56 MHz. The plasma generating apparatus was manufactured for 450 mm substrates, but the electrical probe array was manufactured for 300 mm substrates. The electrical probe array includes electrical probes arranged in a matrix. The electrical probe array was vertically spaced apart from the first electrode by 12 centimeters (cm). Argon gas was used, and pressure was 100 milliTorr (mTorr).

Referring to FIG. 14, when the power of the first RF power source is 50 watts and is supplied to the first electrode and the power of the second RF power source is 200 watts and is supplied to divided second electrodes, non-uniformity of plasma density was 5.4 percent within a measured range of 300 mm. When the power of the first RF power source and the power of the second RF power source are minutely adjusted, the non-uniformity of the plasma density may decrease below 5.4 percent.

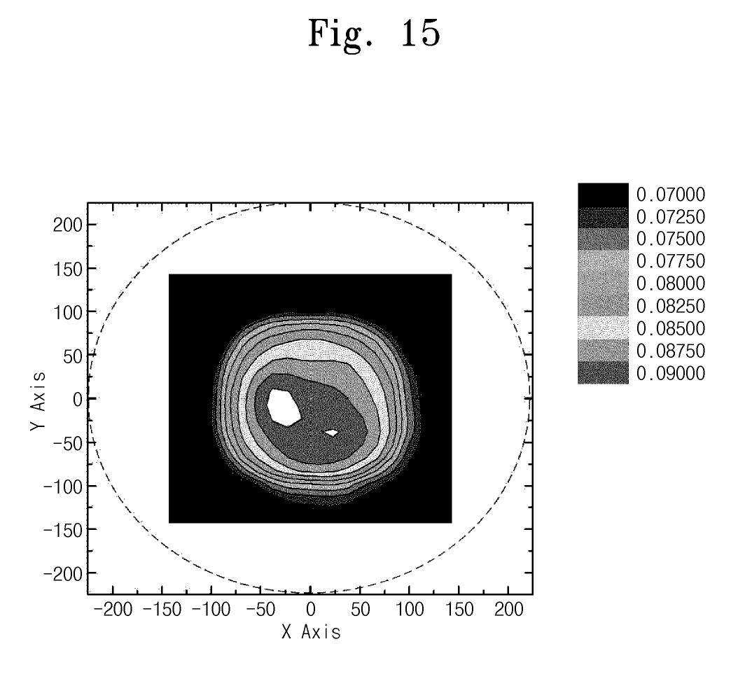

Referring to FIG. 15, when the power of first RF power source is 50 watts and the power of the second RF power source is 300 watts, the non-uniformity of the plasma density was 15.2 percent within the measured range of 30 mm.

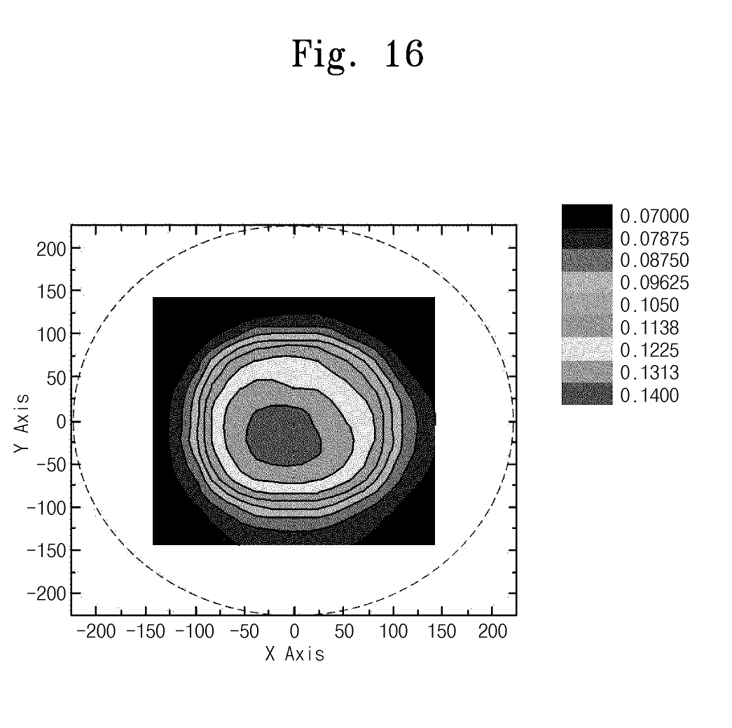

Referring to FIG. 16, when the power of first RF power source is 75 watts and the power of the second RF power source is 200 watts, the non-uniformity of the plasma density was 29.5 percent within the measured range of 30 mm.

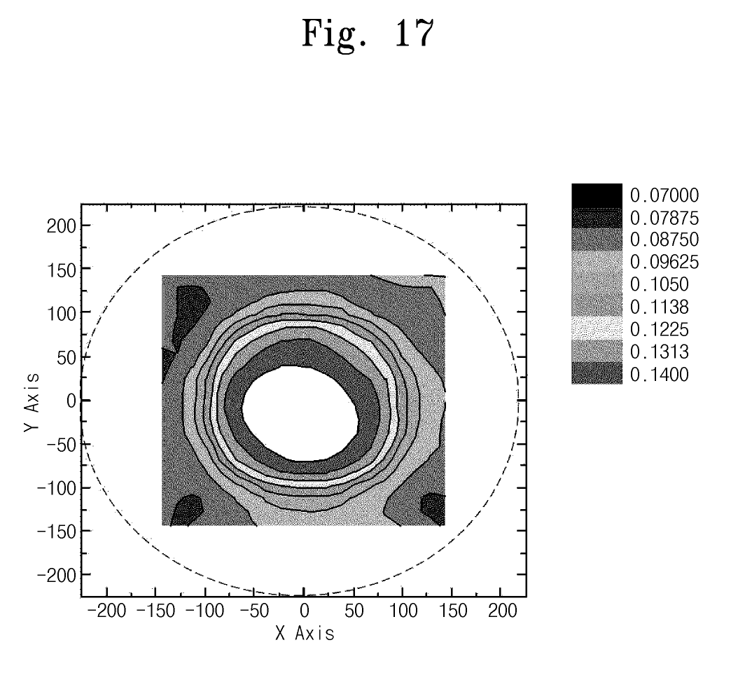

Referring to FIG. 17, when the power of first RF power source is 75 watts and the power of the second RF power source is 300 watts, the non-uniformity of the plasma density was 27.17 percent within the measured range of 30 mm.

As described so far, a substrate processing apparatus according to an embodiment of the present invention can uniformly a large-area semiconductor substrate using plasma.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A plasma generating apparatus comprising:
a disk-shaped first electrode receiving first RF power of a first frequency to generate plasma;
a washer-type second electrode disposed around the circumference of the first electrode and receiving second RF power of a second frequency;
an insulating spacer disposed between the first electrode and the second electrode;
a first RF power source supplying power to the first electrode; and
a second RF power source supplying power to the second electrode.

2. The plasma generating apparatus of claim 1, further comprising:
a first RF power supply unit supplying power to the first electrode; and
a second RF power distribution unit distributing the second RF power to the second electrode.

3. The plasma generating apparatus of claim 2, wherein the second RF power distribution unit comprises:
a power input unit disposed around the circumference of the first RF power supply unit;
a second power distribution line branching radially from the power input unit; and
a ground member covering the second power distribution line,
wherein one end of the second power distribution line is connected to the power input unit, and the other end of the second power distribution line is symmetrically connected to the second electrode.

4. The plasma generating apparatus of claim 3, wherein the second electrode is divided into a plurality of second electrodes cut on its central axis in a radius direction, and each of the divided second electrodes is electrically connected to the other end of the second power distribution line.

5. The plasma generating apparatus of claim 2, wherein the first RF power supply unit comprises at least one of:
a first RF power supply line in contact with the first electrode;
a first RF power inner insulating jacket covering the first power supply line;
a first RF ground outer cover covering the first RF power inner insulating jacket; and
a first RF power outer insulating jacket covering the first RF ground outer cover.

6. The plasma generating apparatus of claim 4, wherein an area of the first electrode is equal to an area of the divided second electrode.

7. The plasma generating apparatus of claim 1, wherein the second frequency is different from the first frequency.

8. The plasma generating apparatus of claim 1, wherein a bottom surface of the first electrode and a bottom surface of the second electrode are different from each other, and
wherein the insulating spacer fills an outer side surface of the first electrode and an inner side surface of the second electrode.

9. The plasma generating apparatus of claim 1, wherein thickness of the first electrode is equal to thickness of the insulating spacer, and
wherein a bottom surface of the second electrode varies outward.

10. The plasma generating apparatus of claim 2, further comprising at least one of:
a third RF power source having a third frequency and supplying power to the first electrode; and
a fourth RF power source having a fourth frequency and supplying power to the second electrode,
wherein power of the third RF power source is supplied to the first electrode through the first RF power supply unit, and
wherein power of the fourth RF power source is supplied to the second electrode through the second RF power supply unit.

11. The plasma generating apparatus of claim 1, further comprising:
a gas diffusion space receiving a gas through an external gas supply line and formed on the first electrode or the second electrode; and
a nozzle connected to the gas diffusion space and penetrating the first electrode or the second electrode.

12. A plasma generating apparatus comprising:
a first electrode;
a second electrode disposed around the circumference of the first electrode;
a first RF power source supplying power to the first electrode;
a second RF power source supplying power to the second electrode; and
a second RF power source distribution unit distributing power to the second electrode,
wherein the second electrode is divided into a plurality of second electrodes.

13. The plasma generating apparatus of claim 12, wherein the first electrode is disk-shaped, and the second electrode is washer-type.

14. The plasma generating apparatus of claim 12, wherein the second RF power distribution unit distributes second RF power to the respective divided second electrodes.

15. The plasma generating apparatus of claim 12, wherein the second RF power distribution unit comprises:
a power input unit receiving second RF power through the second RF power source;
a second power distribution line branching radially from the power input unit; and
a ground member covering the second power distribution line,
wherein the branching power distribution line is connected to the divided second electrode.

16. The plasma generating apparatus of claim 12, wherein the divided second electrodes have the same area.

17. The plasma generating apparatus of claim 12, further comprising:
nozzles formed through the first electrode and the second electrode to supply a gas.

18. A plasma generating apparatus comprising:
a first electrode;
a second electrode disposed around the circumference of the first electrode;
a first RF power source supplying power to the first electrode;
a second RF power source supplying power to the second electrode; and
a second RF power source distribution unit distributing power to the second electrode.

19. The plasma generating apparatus of claim 18, wherein the second RF power distribution unit comprises:
a power input unit receiving second RF power through the second RF power source;
a second power distribution line branching radially from the power input unit; and
a ground member covering the second power distribution line,
wherein the branching power distribution line is connected to the second electrode.

20. The plasma generating apparatus of claim 19, wherein the second electrode is divided to have the same area.

21. A plasma generating apparatus comprising:
a first electrode;
a second electrode disposed around the circumference of the first electrode;
a second RF power source supplying power to the second electrode; and
an insulating support disposed between the first electrode and the second electrode and the second RF power distribution unit to have a gas diffusion space.

22. The plasma generating apparatus of claim 21, wherein the second RF power distribution unit comprises:
a power input unit receiving second RF power through the second RF power source;
a second power distribution line branching radially from the power input unit; and
a ground member covering the second power distribution line,
wherein the branching power distribution line is connected to the second electrode.

23. The plasma generating apparatus of claim 21, further comprising nozzles formed through the first electrode and the second electrode and connected to the gas diffusion space.

24. A substrate processing apparatus comprising:
a plasma generating unit generating capacitively coupled plasma inside a vacuum container; and
a substrate holder disposed to face the plasma generating unit and mounting a substrate,
wherein the plasma generating unit comprises:
a first electrode;
a second electrode disposed around the circumference of the first electrode;
a first RF power source supplying power to the first electrode;
a second RF power source supplying power to the second electrode; and
a second RF power source distribution unit distributing power to the second electrode.

25. The substrate processing apparatus of claim 24, wherein the plasma generating unit is mounted inside the vacuum container or mounted on a lid of the vacuum container.

26. The substrate processing apparatus of claim 24, wherein the second electrode is divided into a plurality of the same second electrodes, and
wherein the second RF power distribution unit comprises:
a power input unit receiving second RF power through the second RF power source;
a second power distribution line branching radially from the power input unit; and
a ground member covering the second power distribution line,
wherein the branching power distribution line is connected to the second electrode.
